(19) United States
(12) Patent Application Publication
(10) Pub. No.: US 2026/0245523 A1
(43) Pub. Date: Aug. 20, 2026

(54) SHIFT REGISTER, DRIVING METHOD THEREOF, GATE DRIVING CIRCUIT AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yao HUANG, Beijing (CN); Jun YAN, Beijing (CN); Tingliang LIU, Beijing (CN); Ansu LEE, Beijing (CN); Mengmeng DU, Beijing (CN)

(21) Appl. No.: 19/151,611

(22) PCT Filed: Jun. 12, 2024
(86) PCT No.: PCT/CN2024/098582

§ 371 Date: Jul. 28, 2025

(30) Foreign Application Priority Data
Jul. 26, 2023 (CN) 202310926791.X

(51) Int. Cl. G09G 3/3266; G11C 19/28

(52) U.S. Cl. CPC G09G 3/3266; G11C 19/28; G09G 2310/0286; G09G 2330/021

(57) ABSTRACT

A shift register, a method for driving a shift register, a gate driving circuit and a display apparatus are disclosed. The shift register includes: an input sub-circuit configured to transmit a signal at an input terminal to a first node in response to a first level signal at a first clock signal terminal; a first output sub-circuit configured to transmit a first level signal at a first level signal terminal to an output terminal in response to a first level signal at the first node; a first control sub-circuit configured to transmit a signal at a second level signal terminal to a second node in response to a first level signal at the input terminal; a second control sub-circuit configured to transmit a signal at the first level signal terminal to a third node in response to a first level signal at the first clock signal terminal.

### TECHNICAL FIELD

The present disclosure relates to the field of display technology, and in particular to a shift register, a method for driving a shift register, a gate driving circuit and a display apparatus.

### BACKGROUND

With the continuous development of display technology, in recent years, a display is gradually developing towards a trend of high integration and low cost. One very important technology is to realize mass production of gate driver on arrays (GOAs).

A shift register circuit composed of thin film transistors (TFTs) is integrated on an array substrate of a display substrate by using the GOA technology for scanning and driving the display substrate.

### SUMMARY

The present disclosure provides a shift register, a method for driving a shift register, a gate driving circuit and a display apparatus.

In a first aspect, the present disclosure provides a shift register, including: an input sub-circuit configured to transmit a signal at an input terminal to a first node in response to a first level signal at a first clock signal terminal; a first output sub-circuit configured to transmit a first level signal at a first level signal terminal to an output terminal in response to a first level signal at the first node; a first control sub-circuit configured to transmit a second level signal at a second level signal terminal to a second node in response to a first level signal at the input terminal; a second control sub-circuit configured to transmit a first level signal at the first level signal terminal to a third node in response to a first level signal at the first clock signal terminal, and transmit a second level signal at the second level signal terminal to the third node in response to a first level signal at the second clock signal terminal; a storage sub-circuit configured to store a voltage between the second node and the third node; and a second output sub-circuit configured to electrically connect the second level signal terminal with the output terminal in response to a second level signal at the first node and a first level signal at the second node, and maintain an on/off state between the second level signal terminal and the output terminal in response to a second level signal at the first node and a second level signal at the second node.

In some embodiments, the first control sub-circuit includes: a second transistor, wherein a control electrode of the second transistor is electrically connected to the input terminal, a first electrode of the second transistor is electrically connected to the second level signal terminal, and a second electrode of the second transistor is electrically connected to the second node.

In some embodiments, the second control sub-circuit includes: a fifth transistor, wherein a control electrode of the fifth transistor is electrically connected to the first clock signal terminal, a first electrode of the fifth transistor is electrically connected to the first level signal terminal, and a second electrode of the fifth transistor is electrically connected to the third node; and a sixth transistor, wherein a control electrode of the sixth transistor is electrically connected to the second clock signal terminal, a first electrode of the sixth transistor is electrically connected to the second level signal terminal, and a second electrode of the sixth transistor is electrically connected to the third node.

In some embodiments, the storage sub-circuit includes: a first capacitor, wherein two terminals of the first capacitor are electrically connected to the third node and the second node, respectively.

In some embodiments, the input sub-circuit includes: a first transistor, wherein a control electrode of the first transistor is electrically connected to the first clock signal terminal, a first electrode of the first transistor is electrically connected to the input terminal, and a second electrode of the first transistor is electrically connected to the first node.

In some embodiments, the first output sub-circuit includes: an eighth transistor, wherein a control electrode of the eighth transistor is electrically connected to the first node, a first electrode of the eighth transistor is electrically connected to the first level signal terminal, and a second electrode of the eighth transistor is electrically connected to the output terminal; and a second capacitor, wherein two terminals of the second capacitor are electrically connected to the output terminal and the first node, respectively.

In some embodiments, the second output sub-circuit includes: a first control unit configured to transmit a first level signal at the first level signal terminal or a signal at the first clock signal terminal to a fourth node in response to a first level signal at the second node; a second control unit configured to transmit a second level signal at the second level signal terminal to the fourth node in response to a first level signal at the first node; and an output unit configured to transmit a second level signal at the second level signal terminal to the output terminal in response to a first level signal at the fourth node.

In some embodiments, the first control unit includes: a third transistor, wherein a control electrode of the third transistor is electrically connected to the second node, a first electrode of the third transistor is electrically connected to the first level signal terminal or the first clock signal terminal, and a second electrode of the third transistor is electrically connected to the fourth node.

In some embodiments, the second control unit includes: a fourth transistor, wherein a control electrode of the fourth transistor is electrically connected to the first node, a first electrode of the fourth transistor is electrically connected to the second level signal terminal, and a second electrode of the fourth transistor is electrically connected to the fourth node.

In some embodiments, the output unit includes: a seventh transistor, wherein a control electrode of the seventh transistor is electrically connected to the fourth node, a first electrode of the seventh transistor is electrically connected to the second level signal terminal, and a second electrode of the seventh transistor is electrically connected to the output terminal.

In a second aspect, the present disclosure provides a method for driving the above shift register, including: in a first stage, providing, by the input terminal and the second level signal terminal, a first level signal, providing, by the first clock signal terminal, a second level signal, transmitting, by the first control sub-circuit, a second level signal at the second level signal terminal to the second node, transmitting, by the second control sub-circuit, a second level signal at the second level signal terminal to the third node, and electrically connecting, by the second output sub-circuit, the second level signal terminal to the output terminal; in a second stage, providing, by the input terminal and the first clock signal terminal, a first level signal, providing, by the second clock signal terminal, a second level signal, transmitting, by the input sub-circuit, a signal at the input terminal to the first node, transmitting, by the first output sub-circuit, a first level signal at the first level signal terminal to the output terminal, transmitting, by the first control sub-circuit, a second level signal at the second level signal terminal to the second node, and transmitting, by the second control sub-circuit, a first level signal at the first level signal terminal to the third node; in a third stage, providing, by the input terminal and the first clock signal terminal, a second level signal, providing, by the second clock signal terminal, a first level signal, transmitting, by the first output sub-circuit, a first level signal at the first level signal terminal to the output terminal, and transmitting, by the second control sub-circuit, a second level signal at the second level signal terminal to the third node; and in a fourth stage, providing, by the input terminal and the second clock signal terminal, a second level signal, providing, by the first clock signal terminal, a first level signal, transmitting, by the second control sub-circuit, a first level signal at the first level signal terminal to the third node, stabilizing, by the storage sub-circuit, a voltage between the second node and the third node so that a potential at the second node is changed with a potential at the third node, and electrically connecting, by the second output sub-circuit, the second level signal terminal with the output terminal.

In a third aspect, the present disclosure further provides a gate driving circuit, which includes a plurality of cascaded shift registers, where each shift register is the above shift register.

In a fourth aspect, the present disclosure further provides a display apparatus including the gate driving circuit.

### BRIEF DESCRIPTION OF DRAWINGS

The accompanying drawings, which are provided for further understanding of the present disclosure and constitute a part of this specification, are for explaining the present disclosure together with the embodiments of the present disclosure, but are not intended to limit the present disclosure. In the drawings:

FIG. 1 is a schematic diagram of a shift register provided in some embodiments of the present disclosure.

FIG. 2 is a schematic diagram of a shift register provided in further embodiments of the present disclosure.

FIG. 3 is a schematic diagram of a shift register provided in further embodiments of the present disclosure.

FIG. 4 is a timing diagram of a shift register provided in some embodiments of the present disclosure.

FIG. 5 is a waveform diagram illustrating signals at output terminals corresponding to different threshold voltage offsets provided in some embodiments of the present disclosure.

FIG. 6 is a schematic diagram illustrating a method for driving a shift register provided in some embodiments of the present disclosure.

### DETAIL DESCRIPTION OF EMBODIMENTS

The embodiments of the present disclosure will be described in detail hereinafter with reference to the accompanying drawings. It should be understood that the detail description of embodiments described here are only used to illustrate and explain the present disclosure, rather than liming the present disclosure.

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few, not all of, embodiments of the present disclosure. All other embodiments, which can be derived by a person skilled in the art from the embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Similarly, the term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

It should be noted that transistors used in the embodiments of the present disclosure may be thin film transistors or field effect transistors or other devices with the same characteristics. A source electrode and a drain electrode of each transistor are symmetrical, and therefore, there is no difference between the source electrode and the drain electrode. In the embodiments of the present disclosure, in order to distinguish the source electrode and the drain electrode of the transistor, one of the source electrode and the drain electrode is referred to as a first electrode, the other electrode is referred to as a second electrode, and a gate electrode is referred to as a control electrode. In addition, transistors may be divided into N-type and P-type according to the characteristics of the transistors, and in the following embodiments, the transistors are N-type transistors as an example. With the N-type transistor, the first electrode is the source electrode of the N-type transistor, and the second electrode is the drain electrode of the N-type transistor. When a high level is input to the gate electrode, the source electrode and the drain electrode are electrically connected to each other. When a low level is input to a gate electrode of a P-type transistor, a source electrode and a drain electrode of the P-type transistor are electrically connected to each other. It is contemplated that implementation with P-type transistors will be readily apparent to one of ordinary skill in the art without inventive effort and thus, are within the scope of the embodiments of the present disclosure. In addition, the transistors may be divided into oxide thin film transistors, low temperature polysilicon thin film transistors, and the like according to a material of an active layer in the transistors. Generally, the oxide thin film transistor is an N-type transistor, and the low temperature polysilicon thin film transistor is a P-type transistor.

In the present disclosure, a “first level signal”/“first level potential” refers to a signal/potential which may control the transistor to be turned on when the signal/potential is input to the control electrode of the transistor, and a “second level signal” refers to a signal/potential which may control the transistor to be turned off when the signal/potential is input to the control electrode of the transistor. In some embodiments, the first level signal may be a high level signal, the first level potential is a high level potential, the second level signal may be a low level signal, and a second level potential is a low level potential. In other embodiments, the first level signal is a low level signal, the first level potential is a low level potential, the second level signal is a high level signal, and the second level potential is a high level potential. For the N-type transistor, the first level signal is a high level signal, the first level potential is a high level potential, the second level signal is a low level signal, and the second level potential is a low level potential. For the P-type transistor, the first level signal is a low level signal, the first level potential is a low level potential, the second level signal is a high level signal, and the second level potential is a high level potential.

In a display substrate, a plurality of gate lines and a plurality of data lines cross each other in a display region to define a plurality of pixels, and each pixel is provided with a pixel circuit and a light emitting device. An operation stage of the pixel circuit includes a data writing stage and a luminescent stage. In the data writing stage, the pixel circuit writes a data voltage and a threshold voltage into a storage capacitor in response to scanning signals on the gate lines for threshold compensation. In the luminescent stage, the pixel circuit provides a driving current to the light emitting device in response to a luminescent control signal on a luminescent control line. The light emitting device includes a plurality of structures, which may be selected according to actual needs. For example, the light emitting device may be an OLED (organic light emitting diode), a quantum dot light emitting diode (QLED), or a micro light emitting diode (micro LED) or the like.

A plurality of gate driving circuits are arranged in a peripheral region of the display substrate and include a plurality of cascaded shift registers. For example, a first gate driving circuit and a second gate driving circuit are arranged in the peripheral region, the first gate driving circuit includes a plurality of cascaded first shift registers connected to the gate lines, and configured to sequentially provide scanning signals to the plurality of gate lines. The second gate driving circuit includes a plurality of cascaded second shift registers connected to the luminescent control lines, and configured to sequentially provide luminescent control signals to the luminescent control lines.

How to reduce the power consumption of the shift register is a problem of continuous attention in the art.

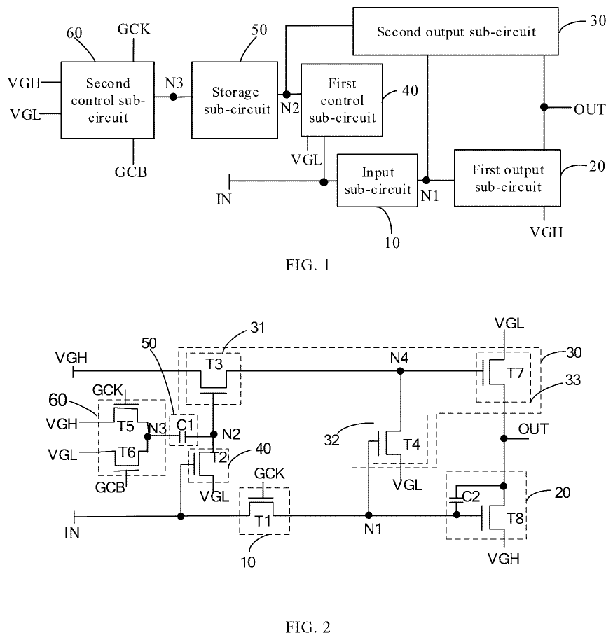

FIG. 1 is a schematic diagram of a shift register provided in some embodiments of the present disclosure. As shown in FIG. 1, the shift register includes: an input sub-circuit 10, a first output sub-circuit 20, a first control sub-circuit 40, a second control sub-circuit 60, a storage sub-circuit 50 and a second output sub-circuit 30.

The input sub-circuit 10 is electrically connected to an input terminal IN of the shift register, a first clock signal terminal GCK, and a first node N1, and is configured to transmit a signal at the input terminal IN to the first node N1 in response to a first level signal at the first clock signal terminal GCK.

The first output sub-circuit 20 is connected to the first node N1, a first level signal terminal VGH, and an output terminal OUT of the shift register, and is configured to transmit a first level signal at the first level signal terminal VGH to the output terminal OUT in response to a first level signal at the first node N1.

The first control sub-circuit 40 is electrically connected to the input terminal IN, a second level signal terminal VGL, and a second node N2, and is configured to transmit a second level signal at the second level signal terminal VGL to the second node N2 IN response to a first level signal at the input terminal IN.

The second control sub-circuit 60 is electrically connected to the first clock signal terminal GCK, a third node N3, a second clock signal terminal GCB, the first level signal terminal VGH, and the second level signal terminal VGL, and is configured to transmit a first level signal at the first level signal terminal VGH to the third node N3 in response to a first level signal at the first clock signal terminal GCK, and transmit a second level signal at the second level signal terminal VGL to the third node N3 in response to a first level signal at the second clock signal terminal GCB.

The storage sub-circuit 50 is electrically connected to the second node N2 and the third node N3, and is configured to store a voltage between the second node N2 and the third node N3.

The second output sub-circuit 30 is electrically connected to the second node N2, the second level signal terminal VGL, the output terminal OUT, the first level signal terminal VGH, and the first node N1, and configured to electrically connect the second level signal terminal VGL with the output terminal OUT in response to a second level signal at the first node N1 and a first level signal at the second node N2, and maintain an on/off state between the second level signal terminal VGL and the output terminal OUT in response to a second level signal at the second node N2 and a second level signal at the first node N1. In some embodiments, the second output sub-circuit 30 is further configured to disconnect the output terminal OUT from the second level signal terminal VGL in response to a first level signal at the first node N1.

In the embodiment of the present disclosure, an operation process of the shift register may include at least a first stage to a fourth stage. In the first stage, the input terminal IN and the second clock signal terminal GCB provide a first level signal, and the first clock signal terminal GCK provides a second level signal. The first node N1 holds a second level potential in the previous stage, and the input sub-circuit 10 transmits a second level signal at the second level signal terminal VGL to the second node N2. The second control sub-circuit 60 transmits a second level signal at the second level signal terminal VGL to the third node N3. The second output sub-circuit 30 maintains the electric connection between the second level signal terminal VGL and the output terminal OUT, and the output terminal OUT outputs a second level signal.

In the second stage, the input terminal IN and the first clock signal terminal GCK provide a first level signal, and the second clock signal terminal GCB provides a second level signal. The input sub-circuit 10 transmits a first level signal at the input terminal IN to the first node N1. The first output sub-circuit 20 transmits a first level signal at the first level signal terminal VGH to the output terminal OUT, thereby causing the output terminal OUT to output a first level signal. The first control sub-circuit 40 transmits a second level signal at the second level signal terminal VGL to the second node N2, and the second control sub-circuit 60 transmits a first level signal at the first level signal terminal VGH to the third node N3.

In the third stage, the input terminal IN and the first clock signal terminal GCK provide a second level signal, the second clock signal terminal GCB provides a first level signal, the input terminal IN is disconnected from the first node N1, and the first node N1 maintains the first level potential. The first output sub-circuit 20 transmits a first level signal at the first level signal terminal VGH to the output terminal OUT, and the second output sub-circuit 30 disconnects the output terminal OUT from the second level signal terminal VGL. The second control sub-circuit 60 transmits a second level signal at the second level signal terminal VGL to the third node N3.

In the fourth stage, the first clock signal terminal GCK provides a first level signal, and the input terminal IN and the second clock signal terminal GCB provide a second level signal. The input sub-circuit 10 transmits a second level signal at the input terminal IN to the first node N1, and the second control sub-circuit 60 transmits a first level signal at the first level signal terminal VGH to the third node N3. The second node N2 is floating, so that a potential at the second node N2 is changed with a potential at the third node N3, and is changed from a second level potential to a first level potential. The second output sub-circuit 30 transmits a second level signal at the second level signal terminal VGL to the output terminal OUT.

It can be seen that the input terminal IN starts to provide a first level signal from the start time of the first stage, and stops providing the first level signal at the start time of the third stage. The output terminal OUT starts to output a first level signal at the starting time of the second stage and stops outputting the first level signal at the starting time of the fourth stage, so that the shift function is realized.

In the embodiment of the present disclosure, the second control sub-circuit 60 transmits a first level signal at the first level signal terminal VGH or a second level signal at the second level signal terminal VGL to the storage sub-circuit 50 in response to signals at the first clock signal terminal GCK and the second clock signal terminal GCB, which is equivalent to charging the storage sub-circuit 50 with direct current, which can reduce the power consumption of the shift register in the embodiment of the present disclosure compared to directly charging the storage sub-circuit 50 with the clock signal at the clock signal terminal.

FIG. 2 is a schematic diagram of a shift register provided in further embodiments of the present disclosure. The shift register shown in FIG. 2 is a specific implementation for FIG. 1. FIG. 3 is a schematic diagram of a shift register provided in further embodiments of the present disclosure. The shift register shown in FIG. 3 is another specific implementation for FIG. 1.

As shown in FIGS. 2 and 3, the input sub-circuit 10 includes a first transistor T1, a control electrode of the first transistor Tl is electrically connected to the first clock signal terminal GCK, a first electrode of the first transistor Tl is electrically connected to the input terminal IN, and a second electrode of the first transistor Tl is electrically connected to the first node N1. When the first clock signal terminal GCK provides a first level signal, the first electrode and the second electrode of the first transistor Tl are electrically connected to each other, thereby transmitting a signal at the input terminal IN to the first node N1.

In some embodiments, as shown in FIG. 2, the first output sub-circuit 20 includes: a second capacitor C2 and an eighth transistor T8. A control electrode of the eighth transistor T8 is electrically connected to the first node N1, a first electrode of the eighth transistor T8 is electrically connected to the first level signal terminal VGH, and a second electrode of the eighth transistor T8 is electrically connected to the output terminal OUT. Both terminals of the second capacitor C2 are electrically connected to the output terminal OUT and the first node N1, respectively.

When the first node N1 provides a first level signal (i.e., the first node N1 is at a first level potential), the first electrode and the second electrode of the eighth transistor T8 are electrically connected to each other, thereby electrically connecting the first level signal terminal VGH with the output terminal OUT. When the first node N1 is floating, a voltage between the first node N1 and the output terminal OUT remains unchanged under the voltage stabilization of the second capacitor C2.

In some embodiments, as shown in FIGS. 2 and 3, the first control sub-circuit 40 includes: the second transistor T2, a control electrode of the second transistor T2 is electrically connected to the input terminal IN, a first electrode of the second transistor T2 is electrically connected to the second level signal terminal VGL, and a second electrode of the second transistor T2 is electrically connected to the second node N2. When the input terminal IN provides a first level signal, the first electrode and the second electrode of the second transistor T2 are electrically connected to each other, thereby transmitting a second level signal at the second level signal terminal VGL to the second node N2.

In some embodiments, as shown in FIGS. 2 and 3, the storage sub-circuit 50 includes: a first capacitor C1, and two terminals of the first capacitor Cl are electrically connected to the third node N3 and the second node N2, respectively.

In some embodiments, as shown in FIGS. 2 and 3, the second output sub-circuit 30 includes: a first control unit 31, a second control unit 32, and an output unit 33, wherein the first control unit 31 is electrically connected to the second node N2, and the fourth node N4, the first control unit 31 is further electrically connected to the first level signal terminal VGH or the first clock signal terminal GCK, and the first control unit 31 is configured to transmit a first level signal at the first level signal terminal VGH or a signal at the first clock signal terminal GCK to the fourth node N4 in response to a first level signal at the second node N2.

The second control unit 32 is electrically connected to the first node N1, the fourth node N4, and the second level signal terminal VGL, and is configured to transmit a second level signal at the second level signal terminal VGL to the fourth node N4 in response to a first level signal at the first node N1.

The output unit 33 is electrically connected to the fourth node N4, the second level signal terminal VGL, and the output terminal OUT, and is configured to transmit a second level signal at the second level signal terminal VGL to the output terminal OUT in response to a first level signal at the fourth node N4.

When the first node N1 provides a first level signal, the first control unit 31 transmits a first level signal at the first level signal terminal VGH to the output terminal OUT, and the second control unit 32 transmits a second level signal at the second level signal terminal VGL to the fourth node N4, and the output unit 33 disconnects the second level signal terminal VGL from the output terminal OUT according to the second level signal at the fourth node N4. When the second node N2 provides a first level signal, for example, in the above fourth stage, the first control unit 31 transmits a first level signal at the first level signal terminal VGH or a first level signal at the first clock signal terminal GCK to the fourth node N4, and the output unit 33 electrically connects the second level signal terminal VGL with the output terminal OUT according to the first level signal at the fourth node N4. When the first node N1 and the second node N2 provide a second level signal, the second control unit 32 disconnects the second level signal terminal VGL from the fourth node N4, the first control unit 31 disconnects the first level signal terminal VGH or the first clock signal terminal GCK from the fourth node N4, and at this time, the fourth node N4 maintains the previous first level potential, so that the output unit 33 maintains the electrical connection between the second level signal terminal VGL and the output terminal OUT.

In some embodiments, as shown in FIG. 2, the first control unit 31 includes: a third transistor T3, a control electrode of the third transistor T3 is electrically connected to the second node N2, a first electrode of the third transistor T3 is electrically connected to the first level signal terminal VGH, and a second electrode of the third transistor T3 is electrically connected to the fourth node N4. Alternatively, as shown in FIG. 3, the first control unit 31 includes: a third transistor T3, a control electrode of the third transistor T3 is electrically connected to the second node N2, a first electrode of the third transistor T3 is electrically connected to the first clock signal terminal GCK, and a second electrode of the third transistor T3 is electrically connected to the fourth node N4.

As shown in FIGS. 2 and 3, the second control unit 32 includes: a fourth transistor T4, a control electrode of the fourth transistor T4 is electrically connected to the first node N1, a first electrode of the fourth transistor T4 is electrically connected to the second level signal terminal VGL, and a second electrode of the fourth transistor T4 is electrically connected to the fourth node N4.

As shown in FIGS. 2 and 3, the output unit 33 includes: a seventh transistor T7, a control electrode of the seventh transistor T7 is electrically connected to the fourth node N4, a first electrode of the seventh transistor T7 is electrically connected to the second level signal terminal VGL, and a second electrode of the seventh transistor T7 is electrically connected to the output terminal OUT. The seventh transistor T7 may have a great width to length ratio to form a parasitic capacitance, so that when the fourth node N4 is floating, a potential at the fourth node N4 may be maintained consistent with the potential in the previous stage by the parasitic capacitance of the seventh transistor T7.

In other embodiments, the output unit 33 may further include a third capacitor (not shown) in addition to the seventh transistor T7, two terminals of the third capacitor are electrically connected to the second level signal terminal VGL and the fourth node N4, respectively, and the third capacitor can maintain a potential at the fourth node N4 consistent with the potential in the previous stage when the fourth node N4 is floating.

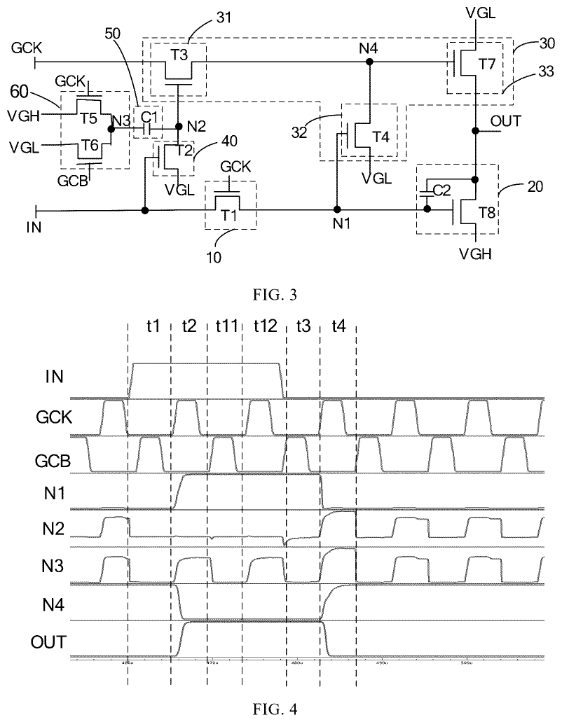

FIG. 4 is a timing diagram of a shift register provided in some embodiments of the present disclosure. The operation of the shift register in the embodiments of the present disclosure is described below with reference to FIGS. 2 to 4. The transistors in the shift register are N-type transistors as an example. At this time, the high level signal serves as a first level signal, and the low level signal serves as a second level signal.

In a first stage t1, the input terminal IN and the second clock signal terminal GCB provide a high level signal, and the first clock signal terminal GCK provides a low level signal. At this time, the second transistor T2 is turned on, and a low level signal at the second level signal terminal VGL is transmitted to the second node N2. In addition, the sixth transistor T6 is turned on, and a low level signal at the second level signal terminal VGL is transmitted to the third node N3. The first transistor T1, the third transistor T3, and the fifth transistor T5 are all turned off, and the first node N1 maintains the low level potential in the previous stage, to maintain the eighth transistor T8 to be turned off. The fourth node N4 maintains the high level potential in the previous stage, thereby turning on the seventh transistor T7, so that a low level signal at the second level signal terminal VGL is output from the output terminal OUT.

In a second stage t2, the input terminal IN and the first clock signal terminal GCK provide a high level signal, and the second clock signal terminal GCB provides a low level signal. At this time, the first transistor Tl is turned on, and the high level signal at the input terminal IN is transmitted to the first node N1, thereby controlling the eighth transistor T8 to be turned on, and thus, a high level signal at the first level signal terminal VGH is transmitted to the output terminal OUT. Meanwhile, the second transistor T2 is turned on, and a low level signal at the second level signal terminal VGL is transmitted to the second node N2. The fifth transistor T5 is turned on, and a high level signal at the first level signal terminal VGH is transmitted to the third node N3, thereby charging the first capacitor C1. Since the second node N2 is at a low level potential and the first node N1 is at a high level potential, the third transistor T3 is turned off, the fourth transistor T4 is turned on, and a low level signal at the second level signal terminal VGL is transmitted to the fourth node N4, thereby controlling the seventh transistor T7 to be turned off, and therefore, preventing the high level output of the output terminal OUT from being affected.

In a first hold stage t11, the input terminal IN and the second clock signal terminal GCB provide a high level signal, and the first clock signal terminal GCK provides a low level signal. At this time, the first transistor T1 is turned off, and the first node N1 maintains the high level potential in the previous stage, so that the eighth transistor T8 is maintained to be turned on, and a high level signal at the first level signal terminal VGH is transmitted to the output terminal OUT. Meanwhile, the second transistor T2 is turned on, and a low level signal at the second level signal terminal VGL is transmitted to the second node N2. The fifth transistor T5 is turned off and the sixth transistor T6 is turned on, so that the low level signal at the second level signal terminal VGL is transmitted to the third node N3. Since the second node N2 is at the low level potential, the third transistor T3 is turned off. The first node N1 is at the high level potential, so that the fourth transistor T4 is turned on, thereby transmitting the low level signal at the second level signal terminal VGL to the fourth node N4, and the seventh transistor T7 is maintained to be turned off.

In a second hold stage t12, the input terminal IN and the first clock signal terminal GCK provide a high level signal, and the second clock signal terminal GCB provides a low level signal. At this time, the first transistor T1 is turned on, and the high level signal at the input terminal IN is transmitted to the first node N1, so that the eighth transistor T8 is maintained to be turned on and the high level signal at the first level signal terminal VGH is transmitted to the output terminal OUT. Meanwhile, the second transistor T2 is turned on, and a low level signal at the second level signal terminal VGL is transmitted to the second node N2. The sixth transistor T6 is turned off and the fifth transistor T5 is turned on, so that the high level signal at the first level signal terminal VGH is transmitted to the third node N3. The third transistor T3, the fourth transistor T4, and the seventh transistor T7 all maintain the on/off states in the previous stage, and the output terminal OUT is maintained to output the high level signal.

In a third stage t3, the input terminal IN and the first clock signal terminal GCK provide a low level signal, and the second clock signal terminal GCB provides a high level signal. At this time, the first transistor T1 is turned off, the first node N1 maintains the high level potential in the previous stage, so that the eighth transistor T8 is maintained to be turned on, and the high level signal at the first level signal terminal VGH is transmitted to the output terminal OUT. Meanwhile, the second transistor T2 is turned off, the fifth transistor T5 is turned off and the sixth transistor T6 is turned on, thereby transmitting the low level signal at the second level signal terminal VGL to the third node N3. Under the voltage stabilization of the first capacitor C1, the second node N2 maintains the low level potential in the previous stage, so that the third transistor T3 is maintained to be turned off. The fourth transistor T4 and the seventh transistor T7 both maintain the on/off states in the previous stage, and the output terminal OUT is maintained to output the high level signal.

In a fourth stage t4, the input terminal IN and the second clock signal terminal GCB provide a low level signal, and the first clock signal terminal GCK provides a high level signal. At this time, the first transistor T1 is turned on, and the low level signal at the input terminal IN is transmitted to the first node N1, thereby turning off the eighth transistor T8 and the fourth transistor T4. Meanwhile, the fifth transistor T5 is turned on, and the sixth transistor T6 is turned off, so that the high level signal at the first level signal terminal VGH is transmitted to the third node N3, and the third node N3 jumps from the low level potential in the previous stage to a high level potential. Since the second transistor T2 is turned off and the second node N2 is floating, under the bootstrap effect of the first capacitor C1, a potential at the second node N2 is changed with a potential at the third node N3, and is changed from the low level potential in the previous stage to a high level potential, so as to control the third transistor T3 to be turned on. Therefore, the high level signal at the first level signal terminal VGH is transmitted to the fourth node N4, so that the seventh transistor T7 is turned on, and the low level signal at the second level signal terminal VGL is transmitted to the output terminal OUT.

After the fourth stage t4, when the first clock signal terminal GCK provides a low level signal and the second clock signal terminal GCB provides a high level signal, the first node N1 maintains the low level potential in the previous stage, thereby controlling the fourth transistor T4 and the eighth transistor T8 to be turned off. Meanwhile, the fifth transistor T5 is turned off, the sixth transistor T6 is turned on, and the third node N3 receives a low level signal at the second level signal terminal VGL. Since the second transistor T2 is turned off under a low level signal at the input terminal IN, and the second node N2 is floating, under the bootstrap effect of the first capacitor C1, a potential at the second node N2 is changed with a potential at the third node N3, and is changed from the high level potential in the previous stage to a low level potential, so as to control the third transistor T3 to be turned off. Therefore, the fourth node N4 maintains the high level potential in the previous stage, so as to turn on the seventh transistor T7, and the output terminal OUT outputs the low level signal at the second level signal terminal VGL.

After the fourth stage t4, when the first clock signal terminal GCK provides a high level signal and the second clock signal terminal GCB provides a low level signal, the potential at each node is consistent with that in the fourth stage, the on/off state of each transistor is consistent with that in the fourth stage, and the output terminal OUT is maintained to output the low level signal.

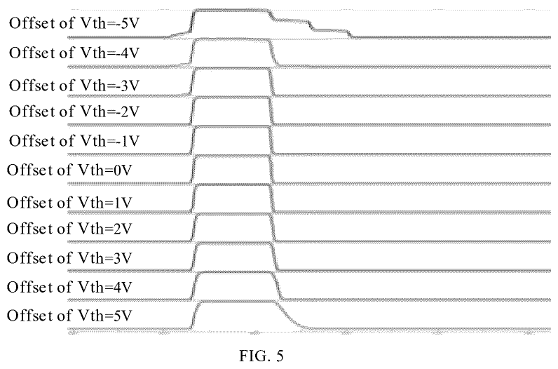

FIG. 5 is a waveform diagram of signals at output terminals OUT corresponding to different threshold voltage offsets provided in some embodiments of the present disclosure. As shown in FIG. 5, when an offset of a threshold voltage Vth of each transistor is between −3V and 4V, the output terminal OUT may normally output signals.

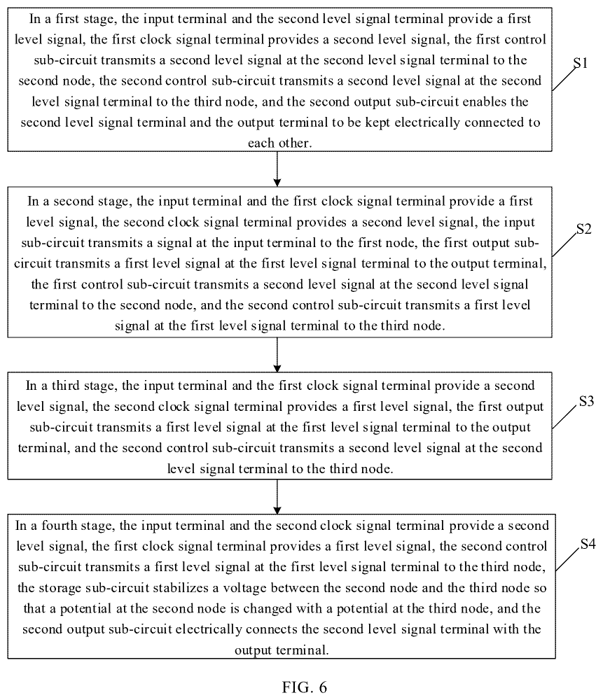

FIG. 6 is a schematic diagram illustrating a method for driving a shift register provided in some embodiments of the present disclosure. The shift register is a shift register in the above embodiments, and as shown in FIG. 6, the method includes steps S1 to S4.

In the step S1, in a first stage, the input terminal and the second level signal terminal provide a first level signal, the first clock signal terminal provides a second level signal, the first control sub-circuit transmits a second level signal at the second level signal terminal to the second node, the second control sub-circuit transmits a second level signal at the second level signal terminal to the third node, and the second output sub-circuit enables the second level signal terminal and the output terminal to be kept electrically connected to each other.

In the step S2, in a second stage, the input terminal and the first clock signal terminal provide a first level signal, the second clock signal terminal provides a second level signal, the input sub-circuit transmits a signal at the input terminal to the first node, the first output sub-circuit transmits a first level signal at the first level signal terminal to the output terminal, the first control sub-circuit transmits a second level signal at the second level signal terminal to the second node, and the second control sub-circuit transmits a first level signal at the first level signal terminal to the third node.

In the step S3, in a third stage, the input terminal and the first clock signal terminal provide a second level signal, the second clock signal terminal provides a first level signal, the first output sub-circuit transmits a first level signal at the first level signal terminal to the output terminal, and the second control sub-circuit transmits a second level signal at the second level signal terminal to the third node.

In the step S4, in a fourth stage, the input terminal and the second clock signal terminal provide a second level signal, the first clock signal terminal provides a first level signal, the second control sub-circuit transmits a first level signal at the first level signal terminal to the third node, the storage sub-circuit stabilizes a voltage between the second node and the third node so that a potential at the second node is changed with a potential at the third node, and the second output sub-circuit electrically connects the second level signal terminal with the output terminal.

The embodiment of the present disclosure further provides a gate driving circuit, which includes a plurality of cascaded shift registers, where each shift register is the shift register in the above embodiments. In the two adjacent stages of shift registers, an output terminal of the shift register in the previous stage is electrically connected to an input terminal of the shift register in the next stage.

The embodiment of the present disclosure further provides a display apparatus, which includes the gate driving circuit.

In some embodiments, the display apparatus is an OLED display apparatus, which includes a display substrate, where the display substrate includes a base substrate and a plurality of pixel units arranged on the base substrate, each pixel unit includes a light emitting device and a pixel circuit electrically connected to the light emitting device, the plurality of pixel circuits may be arranged in an array, and each row of pixel circuits is electrically connected to one gate line and one luminescent control line to receive a scan signal on the gate line and a luminescent control signal on the luminescent control line. The gate driving circuit in the above embodiment may be arranged on the base substrate, and sequentially provide luminescent control signals to the plurality of luminescent control lines.

It should be understood that, the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A shift register, comprising:
an input sub-circuit configured to transmit a signal at an input terminal to a first node in response to a first level signal at a first clock signal terminal;
a first output sub-circuit configured to transmit a first level signal at a first level signal terminal to an output terminal in response to a first level signal at the first node;
a first control sub-circuit configured to transmit a second level signal at a second level signal terminal to a second node in response to a first level signal at the input terminal;
a second control sub-circuit configured to transmit a first level signal at the first level signal terminal to a third node in response to a first level signal at the first clock signal terminal, and transmit a second level signal at the second level signal terminal to the third node in response to a first level signal at the second clock signal terminal;
a storage sub-circuit configured to store a voltage between the second node and the third node; and
a second output sub-circuit configured to electrically connect the second level signal terminal with the output terminal in response to a second level signal at the first node and a first level signal at the second node, and maintain an on/off state between the second level signal terminal and the output terminal in response to a second level signal at the first node and a second level signal at the second node.

2. The shift register of claim 1, wherein the first control sub-circuit comprises:
a second transistor, wherein a control electrode of the second transistor is electrically connected to the input terminal, a first electrode of the second transistor is electrically connected to the second level signal terminal, and a second electrode of the second transistor is electrically connected to the second node.

3. The shift register of claim 1, wherein the second control sub-circuit comprises:
a fifth transistor, wherein a control electrode of the fifth transistor is electrically connected to the first clock signal terminal, a first electrode of the fifth transistor is electrically connected to the first level signal terminal, and a second electrode of the fifth transistor is electrically connected to the third node; and
a sixth transistor, wherein a control electrode of the sixth transistor is electrically connected to the second clock signal terminal, a first electrode of the sixth transistor is electrically connected to the second level signal terminal, and a second electrode of the sixth transistor is electrically connected to the third node.

4. The shift register of claim 1, wherein the storage sub-circuit comprises:
a first capacitor, wherein two terminals of the first capacitor are electrically connected to the third node and the second node, respectively.

5. The shift register of claim 1, wherein the input sub-circuit comprises:
a first transistor, wherein a control electrode of the first transistor is electrically connected to the first clock signal terminal, a first electrode of the first transistor is electrically connected to the input terminal, and a second electrode of the first transistor is electrically connected to the first node.

6. The shift register of claim 1, wherein the first output sub-circuit comprises:
an eighth transistor, wherein a control electrode of the eighth transistor is electrically connected to the first node, a first electrode of the eighth transistor is electrically connected to the first level signal terminal, and a second electrode of the eighth transistor is electrically connected to the output terminal; and
a second capacitor, wherein two terminals of the second capacitor are electrically connected to the output terminal and the first node, respectively.

7. The shift register of claim 1, wherein the second output sub-circuit comprises:
a first control unit configured to transmit a first level signal at the first level signal terminal or a signal at the first clock signal terminal to a fourth node in response to a first level signal at the second node;
a second control unit configured to transmit a second level signal at the second level signal terminal to the fourth node in response to a first level signal at the first node; and
an output unit configured to transmit a second level signal at the second level signal terminal to the output terminal in response to a first level signal at the fourth node.

8. The shift register of claim 7, wherein the first control unit comprises:
a third transistor, wherein a control electrode of the third transistor is electrically connected to the second node, a first electrode of the third transistor is electrically connected to the first level signal terminal or the first clock signal terminal, and a second electrode of the third transistor is electrically connected to the fourth node.

9. The shift register of claim 7, wherein the second control unit comprises:
a fourth transistor, wherein a control electrode of the fourth transistor is electrically connected to the first node, a first electrode of the fourth transistor is electrically connected to the second level signal terminal, and a second electrode of the fourth transistor is electrically connected to the fourth node.

10. The shift register of claim 7, wherein the output unit comprises:
a seventh transistor, wherein a control electrode of the seventh transistor is electrically connected to the fourth node, a first electrode of the seventh transistor is electrically connected to the second level signal terminal, and a second electrode of the seventh transistor is electrically connected to the output terminal.

11. A method for driving the shift register of claim 1, comprising:
in a first stage, providing, by the input terminal and the second level signal terminal, a first level signal, providing, by the first clock signal terminal, a second level signal, transmitting, by the first control sub-circuit, a second level signal at the second level signal terminal to the second node, transmitting, by the second control sub-circuit, a second level signal at the second level signal terminal to the third node, and electrically connecting, by the second output sub-circuit, the second level signal terminal to the output terminal;
in a second stage, providing, by the input terminal and the first clock signal terminal, a first level signal, providing, by the second clock signal terminal, a second level signal, transmitting, by the input sub-circuit, a signal at the input terminal to the first node, transmitting, by the first output sub-circuit, a first level signal at the first level signal terminal to the output terminal, transmitting, by the first control sub-circuit, a second level signal at the second level signal terminal to the second node, and transmitting, by the second control sub-circuit, a first level signal at the first level signal terminal to the third node;
in a third stage, providing, by the input terminal and the first clock signal terminal, a second level signal, providing, by the second clock signal terminal, a first level signal, transmitting, by the first output sub-circuit, a first level signal at the first level signal terminal to the output terminal, and transmitting, by the second control sub-circuit, a second level signal at the second level signal terminal to the third node; and
in a fourth stage, providing, by the input terminal and the second clock signal terminal, a second level signal, providing, by the first clock signal terminal, a first level signal, transmitting, by the second control sub-circuit, a first level signal at the first level signal terminal to the third node, stabilizing, by the storage sub-circuit, a voltage between the second node and the third node so that a potential at the second node is changed with a potential at the third node, and electrically connecting, by the second output sub-circuit, the second level signal terminal with the output terminal.

12. A gate driving circuit, comprising a plurality of cascaded shift registers, wherein each of the plurality of cascaded shift registers is the shift register of claim 1.

13. A display apparatus, comprising the gate driving circuit of claim 12.

14. The shift register of claim 2, wherein the input sub-circuit comprises:
a first transistor, wherein a control electrode of the first transistor is electrically connected to the first clock signal terminal, a first electrode of the first transistor is electrically connected to the input terminal, and a second electrode of the first transistor is electrically connected to the first node.

15. The shift register of claim 2, wherein the first output sub-circuit comprises:
an eighth transistor, wherein a control electrode of the eighth transistor is electrically connected to the first node, a first electrode of the eighth transistor is electrically connected to the first level signal terminal, and a second electrode of the eighth transistor is electrically connected to the output terminal; and
a second capacitor, wherein two terminals of the second capacitor are electrically connected to the output terminal and the first node, respectively.

16. The shift register of claim 2, wherein the second output sub-circuit comprises:
a first control unit configured to transmit a first level signal at the first level signal terminal or a signal at the first clock signal terminal to a fourth node in response to a first level signal at the second node;
a second control unit configured to transmit a second level signal at the second level signal terminal to the fourth node in response to a first level signal at the first node; and
an output unit configured to transmit a second level signal at the second level signal terminal to the output terminal in response to a first level signal at the fourth node.

17. The shift register of claim 3, wherein the input sub-circuit comprises:
a first transistor, wherein a control electrode of the first transistor is electrically connected to the first clock signal terminal, a first electrode of the first transistor is electrically connected to the input terminal, and a second electrode of the first transistor is electrically connected to the first node.

18. The shift register of claim 3, wherein the first output sub-circuit comprises:
an eighth transistor, wherein a control electrode of the eighth transistor is electrically connected to the first node, a first electrode of the eighth transistor is electrically connected to the first level signal terminal, and a second electrode of the eighth transistor is electrically connected to the output terminal; and
a second capacitor, wherein two terminals of the second capacitor are electrically connected to the output terminal and the first node, respectively.

19. The shift register of claim 3, wherein the second output sub-circuit comprises:
a first control unit configured to transmit a first level signal at the first level signal terminal or a signal at the first clock signal terminal to a fourth node in response to a first level signal at the second node;
a second control unit configured to transmit a second level signal at the second level signal terminal to the fourth node in response to a first level signal at the first node; and
an output unit configured to transmit a second level signal at the second level signal terminal to the output terminal in response to a first level signal at the fourth node.

20. The shift register of claim 4, wherein the input sub-circuit comprises:
a first transistor, wherein a control electrode of the first transistor is electrically connected to the first clock signal terminal, a first electrode of the first transistor is electrically connected to the input terminal, and a second electrode of the first transistor is electrically connected to the first node;
wherein the first output sub-circuit comprises:
an eighth transistor, wherein a control electrode of the eighth transistor is electrically connected to the first node, a first electrode of the eighth transistor is electrically connected to the first level signal terminal, and a second electrode of the eighth transistor is electrically connected to the output terminal; and
a second capacitor, wherein two terminals of the second capacitor are electrically connected to the output terminal and the first node, respectively;
wherein the second output sub-circuit comprises:
a first control unit configured to transmit a first level signal at the first level signal terminal or a signal at the first clock signal terminal to a fourth node in response to a first level signal at the second node;
a second control unit configured to transmit a second level signal at the second level signal terminal to the fourth node in response to a first level signal at the first node; and
an output unit configured to transmit a second level signal at the second level signal terminal to the output terminal in response to a first level signal at the fourth node.
